(19) United States
(12) Patent Application Publication
(10) Pub. No.: US 2007/0296049 A1
(43) Pub. Date: Dec. 27, 2007

(54) Moveable barriers with obstruction detection

(76) Inventors: William G. Gioia, Winfield, IL (US); Daniel Dombkowski, Schaumburg, IL (US); James Fitzgibbon, Batavia, IL (US)

Correspondence Address: FITCH EVEN TABIN AND FLANNERY, 120 SOUTH LA SALLE STREET, SUITE 1600, CHICAGO, IL, 60603-3406, US

(21) Appl. No.: 11/474,542

(22) Filed: Jun. 26, 2006

(51) Int. Cl. H01L 31/0232

(52) U.S. Cl. 257/432

(57) ABSTRACT

A system includes a photo beam detector. The photobeam detector senses a presence of an obstruction. The system also includes an apparatus to attach the photo beam detector to the moveable barrier. At least a portion of the photo beam detector is positioned at the moveable barrier such that a movement of the moveable barrier causes a simultaneous rotation of the portion of the photo beam detector. The system also includes a coupler and a controller. The controller is coupled to the photo beam detector via the coupler. The controller is programmed to determine whether the obstruction exists in a pathway of the moveable barrier from input received from the photo beam detector.

### FIELD OF THE INVENTION

The field of the invention relates to moveable barrier operators and, more specifically, to sensors for detecting obstructions in the pathways of barriers.

### BACKGROUND

Different types of moveable barrier operators have been sold over the years and these systems have been used to actuate various types of moveable barriers. For example, garage door operators have been used to move garage doors and gate operators have been used to open and close gates.

Such barrier movement operators may include a wall control unit, which is connected to send signals to a head unit thereby causing the head unit to open and close the barrier. In addition, these operators often include a receiver unit at the head unit to receive wireless transmissions from a hand-held code transmitter or from a keypad transmitter, which may be affixed to the outside of the area closed by the barrier or other structure.

Obstructions sometimes become situated in the pathway of barriers such as a garage doors. For instance, portions of vehicles or other items enter the pathway of the door. If the door strikes these obstructions, then the obstruction, the barrier, and/or the barrier operator system may become damaged. In order to prevent damage from occurring, obstruction detection systems have been used. For example, a light emitter and detector are sometimes used to detect obstructions. In this case, when an object interrupts the beam of light between the emitter and detector, an obstruction is determined to be present in the pathway of the door.

Swinging gates are typically used at entrances and allow vehicles to enter a restricted area. Fixed IR beam obstruction detectors are often used in these arrangements. Unfortunately, when vehicles or other obstructions are present, there is the possibility that the beam misses part of the obstruction. For instance, the bumper of the vehicle may remain above or below beam. In addition, in swinging door or gate systems, since the obstruction detectors are fixed, there is the possibility that an object such as a bicycle may be in the pathway of the door or gate (as the door or gate swings) and the detectors will miss detection of the object. Consequently, because of these problems, objects that are in the pathway of the gate will be missed and collisions may occur.

### SUMMARY

A system and method are provided that allow the sensor or part of the sensor to rotate with the barrier. In one particularly useful example of rotation, a barrier such as a gate arm, rotates in a sweeping arc movement from a closed position (i.e., the barrier extends parallel to the ground) to an open position (i.e., the barrier arm is swept upward to be nearly perpendicular to the ground) and vice versa. Since the sensor moves along with the barrier, objects that are in the pathway of the door will be detected as the barrier rotates. Consequently, objects that might remain undetected if the sensor were fixed are detected and damage to the barrier, barrier operator system and/or the object is avoided.

In accordance with the principles described herein, a system includes a photo beam detector. The photobeam detector senses the presence of an obstruction. The system also includes an apparatus to attach the photo beam detector to the moveable barrier. At least a portion of the photo beam detector is positioned at the moveable barrier such that a movement of the moveable barrier causes a simultaneous rotation of the portion of the photo beam detector. The system also includes a coupler and a controller. The controller is coupled to the photo beam detector via the coupler. The controller is programmed to determine whether the obstruction exists in a pathway of the moveable barrier based upon input received from the photo beam detector. The coupler can be any number of arrangements such as a wired connection or a wireless connection.

The photo beam detector can include a variety of components. For example, the photo beam detector may include an emitter and a detector and the emitter and detector may track an edge of the moveable barrier. In another example, the photo detector comprises may include and emitter, a detector, and a reflector (e.g., a mirror). At least a portion of the photo detector may be embedded in the barrier.

In still other examples, the moveable barrier may comprise an arm and the emitter and the detector is positioned at a first end of the arm and the reflector is coupled to an opposite end of the arm. In another approach, the emitter and detector are coupled to the barrier operator and the reflector is coupled to the arm. In still another example, the emitter at least partially embedded in the arm, and the reflector is coupled to the end of the arm.

The moveable barrier may include a variety of different types of barriers. For example, the moveable barrier may be a garage door, a swinging gate, and a sliding gate. Other types of barriers may also be used.

Thus, approaches are provided that are able to detect objects in the paths of barriers such as swinging gates or doors. Since at least some portions of the sensor rotate with the barrier, objects that might remain undetected that went undetected are detected and damage to the objects, the barrier operator system and/or the barrier is prevented.

### BRIEF DESCRIPTION OF THE DRAWINGS

FIG. 1 is a diagram of a movable barrier operator system providing obstruction detection according to the present invention;

FIG. 2 is a diagram of another example of a moveable barrier operator system providing obstruction detection according to the present invention; and

FIG. 3 is a diagram of another example of a moveable barrier operator system providing obstruction detection according to the present invention.

Skilled artisans will appreciate that elements in the figures are illustrated for ease of understanding and have not necessarily been drawn to scale. For example, the dimensions of some of the elements in the figures may be exaggerated relative to other elements to help to improve understanding of various embodiments of the present invention. Also, common but well-understood elements that are useful in a commercially feasible embodiment are often not depicted in order to facilitate a less obstructed view of the various embodiments of the present invention.

### DESCRIPTION

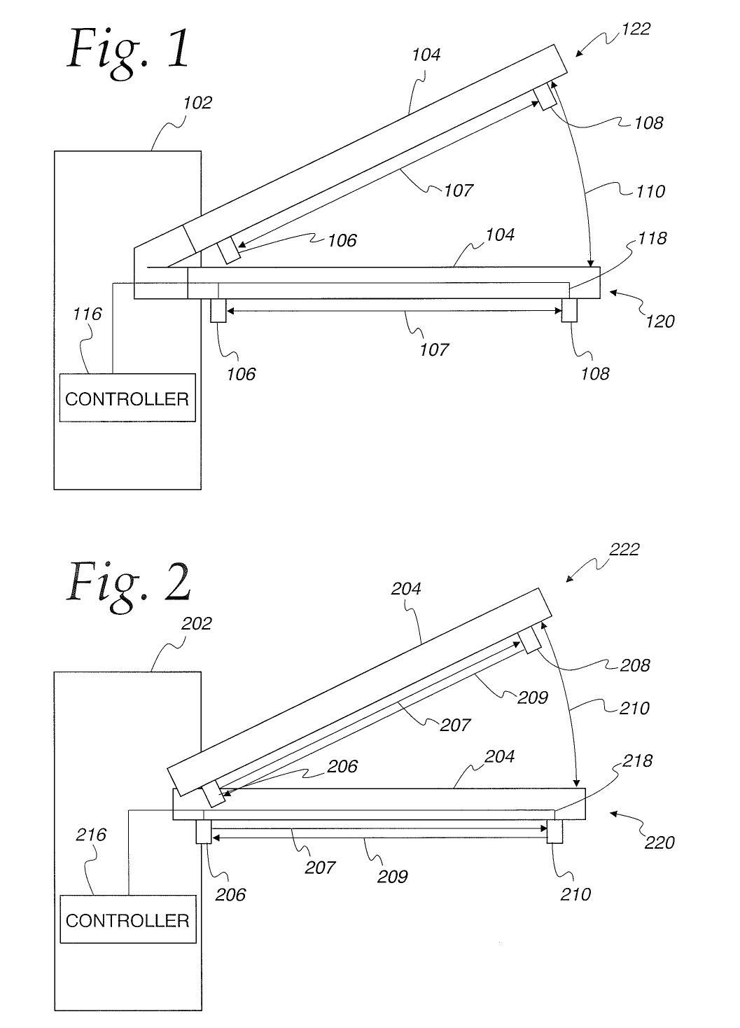

Referring now to the drawings and especially FIG. 1, one example of a barrier operator system where at least a portion of the photo detector rotates with the barrier is described. A barrier 104 is attached to a barrier operator 102. The barrier operator 102 moves the barrier in a sweeping arc movement 110 from a first position 120 to a second position 122. In the first position 120, the barrier is closed while in the second position, the barrier is open. As can be seen, the barrier 104 rotates in a sweeping arc movement between open positions and closed positions.

In this example, the barrier 104 is a gate arm and the barrier operator 102 is a gate operator. However, other types of barriers (e.g., swinging gates, sliding gates, and garage doors) and barrier operators (e.g., gate operators and garage door operators) may be used.

A photo detector includes an emitter 106 and a detector 108. The emitter 106 transmits an energy beam 107 and the transmitted energy beam 107 is detected by the detector 108. In one example, the energy beam 107 may be visible or infrared light. If an obstruction is present in the pathway of the barrier 104, the energy beam is interrupted and not detected by the detector 108. When an obstruction is detected, the operator 102 may take action, for instance, by halting movement of the barrier 104. An apparatus may be used to secure the emitter 106 and detector 108 to the barrier 104. In one example, the apparatus may be screws, nails, brackets, or some combination of these elements.

A controller 116 is coupled to the emitter 106 and the detector 108 by a coupler 118. The coupler 118 may be a wired connection or an unwired connection. The controller 116 is programmed to determine whether an obstruction exists in a pathway of the moveable barrier 104 based upon input received from the photo beam detector (emitter 106 and detector 108).

As the barrier 104 rotates in the movement 110, it detects all obstructions that are present in the path of the barrier 104 as the barrier 104 rotates. For example, if a bumper 104 of a vehicle were positioned below the barrier 104 (while the barrier 104 was in position 122) and the barrier were closed, the bumper would be detected as the barrier 104 came down to the position 120. This approach is advantageous over previous approaches wherein the emitter 106 and 108 were both in a fixed position since, in these previous approaches, the bumper or other obstruction would remain undetected.

Another emitter/detector pair may be positioned at the top of the barrier 104. In addition, the emitter 106 may be positioned on the operator 102. In this case, the emitter 106 remains fixed while the detector 108 rotates. The emitter 106 and detector 108 may also be partially embedded in the barrier 104.

Referring now to FIG. 2, another example of a barrier operator system where at least a part of the photo detector rotates with the barrier is described. A barrier 204 is attached to a barrier operator 202. The barrier operator 202 moves the barrier in an arc movement 210 from a first position 220 to a second position 222. In the first position 220, the barrier is closed while in the second position the barrier is open. As can be seen, the barrier 204 rotates in a sweeping arc movement between open positions and closed positions.

In this example, the barrier 204 is a gate arm and the barrier operator 202 is a gate operator. However, other types of barriers (e.g., swinging gates, sliding gates, and garage doors) and barrier operators (e.g., gate operators and garage door operators) may be used.

A photo detector includes an emitter/detector 206 and a reflector 208. The emitter/detector 206 transmits an energy beam 207 and the transmitted energy is detected by the detector 207. In one example, the energy beam 207 may be visible or infrared light. If an obstruction is present in the pathway of the barrier 204, the energy beam 207 is interrupted and not detected by the emitter/detector 206. The operator 202 can take action, for instance, halting movement of the barrier. An apparatus may be used to secure the emitter/detector 206 to the barrier 204. In one example, the apparatus may be screws, nails, brackets, or some combination of these elements. Other examples of an apparatus are possible.

A controller 216 is coupled to the emitter 206 and the detector 208 by a coupler 218. The coupler 218 may be a wired connection or an unwired connection. The controller 216 is programmed to determine whether the obstruction exists in a pathway of the moveable barrier 204 based upon input received from the photo beam detector (emitter/detector 206 and reflector 208).

As the barrier 204 rotates in the movement 210, it detects all obstructions that are present in the path of the barrier 204 as the barrier 204 rotates. For example, if a bumper 204 of a vehicle were positioned below the barrier 204 (while the barrier 204 was in position 222) and the barrier closed, the bumper would be detected as the barrier 204 came down to position 220. This approach is advantageous over previous approaches wherein the emitter 206 and 208 were both fixed since and the bumper may remain undetected.

Another emitter/detector/reflector may be positioned at the top of the barrier 204. In addition, the emitter/detector 206 may be positioned on the operator 202. In this case, the emitter/detector 206 remains fixed while the reflector 208 rotates. The emitter/detector 206 and reflector 208 may also be partially embedded in the barrier 204.

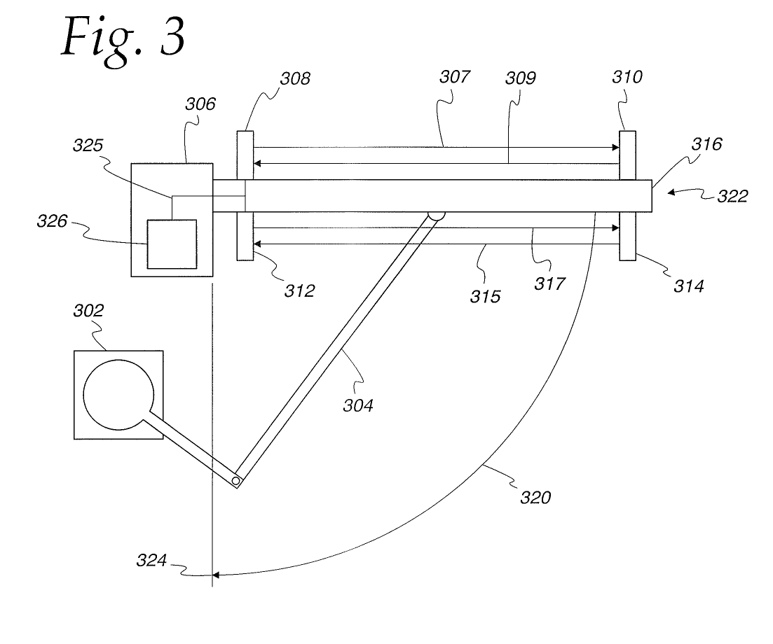

Referring now to FIG. 3, another example of a barrier operator system where at least a part of the photo detector rotates with the barrier is described. A barrier 316 is attached to a barrier operator 306. The barrier operator 306 rotates the barrier in an arc movement 320 from a first position 322 to a second position 324. In the first position 322, the barrier is closed while in the second position 324 that barrier is open. In this example, the barrier 316 is a swinging door or gate and the barrier operator 306 is a swinging door or gate operator. However, other types of barriers (e.g., garage doors) and barrier operators (e.g., garage door operators) may be used. The rotation of the barrier 316 is assisted by a moveable arm 304, which is attached to a base portion 302. The base portion may simply secure the barrier 316 or may additionally include a motor or similar device to drive and move the barrier 316.

A first photo detector on one side of the barrier 316 includes an emitter/detector 308 and a reflector 310. The emitter/detector 308 transmits an energy beam 307 and this energy is reflected as return energy 309 by the reflector 310. In one example, the energy beams 307 and 309 may be visible or infrared light. A second photo detector is located on the opposite side of the barrier 316 and includes an emitter/detector 312 and reflector 314. The emitter/detector 312 transmits an energy beam 317 and this is reflected as energy beam 315 and detected by the emitter detector 312. If an obstruction is present in the pathway of the barrier 316, the energy beams 317 or 309 are not detected by the emitter/detector 308 or the emitter/detector 312. The operator 306 can take action, for instance, by halting movement of the barrier. An apparatus may be used to secure the emitter/detector 308 and emitter/detector 312 to the barrier 316. In one example, the apparatus may be nails, bolts, screws, brackets, or other fastening members. Other examples of an arrangements are possible.

A controller 326 is coupled to the emitter/detector 308 and the emitter/detector 312 by a coupler 328. The coupler 328 may be a wired connection or an unwired connection. The controller 326 is programmed to determine whether the obstruction exists in a pathway of the moveable barrier 316 from input received from the photo beam detector (emitter/detectors 308 and 312, and reflectors 310 and 314).

As the barrier 316 rotates in the movement 320, it detects all obstructions that are present in the path of the barrier 316 as the barrier 316 rotates. For example, if an obstruction (e.g., a person or bicycle) were positioned in the path of the barrier 316 (e.g., along the arc 320) and the barrier 316 opened, the obstruction would be detected as the barrier 316 came down to position 324. In contrast, prior approaches where the sensors are fixed would not detect the obstruction.

Various types of photo detectors may be used. For example, separate emitters and detectors may be used as described with respect to FIG. 1. In addition, the emitter/detectors 308 and 312 may be positioned on the operator 306. In this case, the emitter/detectors 308 and 312 remain fixed while the reflectors 310 and 314 rotate. The emitter/detectors 308 and 312 may also be partially embedded in the barrier 316.

While there has been illustrated and described particular embodiments of the present invention, it will be appreciated that numerous changes and modifications will occur to those skilled in the art, and it is intended in the appended claims to cover all those changes and modifications which fall within the true scope of the present invention.

What is claimed is:

1. A system for operating a moveable barrier comprising:
a photo beam detector for sensing a presence of an obstruction;
an apparatus to attach the photo beam detector to the moveable barrier, at least a portion of the photo beam detector being positioned at the moveable barrier such that a movement of the moveable barrier causes a simultaneous rotation of the portion of the photo beam detector;
a coupler; and
a controller, the controller coupled to the photo beam detector via the coupler, the controller being programmed to determine whether the obstruction exists in a pathway of the moveable barrier from input received from the photo beam detector.

2. The system of claim 1 wherein the coupler is selected from a group comprising a wired connection and a wireless connection.

3. The system of claim 1 wherein the photo beam detector comprises an emitter and a detector, the emitter and detector tracking an edge of the moveable barrier.

4. The system of claim 1 wherein the photo detector comprises an emitter, a detector, and a reflector.

5. The system of claim 4 wherein the moveable barrier comprises and arm and the emitter and the detector are positioned at a first end of the arm and the reflector is coupled to an opposite end of the arm.

6. The system of claim 4 wherein the system comprises a barrier operator, the barrier comprises an arm and wherein the emitter and detector are coupled to the barrier operator and the reflector is coupled to the arm.

7. The system of claim 4 wherein the moveable barrier comprises an arm, the emitter at least partially embedded in the arm, and the reflector is coupled to the end of the arm.

8. The system of claim 1 wherein the moveable barrier is selected from a group comprising a garage door, a swinging gate, and a sliding gate.

9. The system of claim 1 wherein at least a portion of the photo detector is embedded in the barrier.

10. A method of detecting whether an obstruction exists in a pathway of a barrier comprising:
positioning at least a portion of photo beam detector at a moveable barrier; and
actuating and moving the moveable barrier, the moving of the moveable barrier causing a concurrent rotation of the portion of the photo beam detector such that the photo beam detector detects obstructions in a pathway of the moveable barrier as the moveable barrier and the portion of the photo beam detector move together.

11. The method of claim 10 wherein positioning at least a portion of a photo beam detector comprises positioning the entire photo beam detector at the barrier.

12. The method of claim 10 wherein positioning at least a portion of a photo beam detector comprises embedding at least a portion of the photo beam detector at the barrier.

13. The method of claim 10 wherein positioning at least a portion of a photo beam detector comprises positioning a reflector at the barrier.

14. The method of claim 10 wherein positioning at least a portion of a photo beam detector comprises positioning at least a portion of the photo beam detector along a bottom surface of the moveable barrier.

15. The method of claim 10 comprising positioning at least a portion of a photo beam detector at the operator.
